(19) United States
(12) Patent Application Publication
(10) Pub. No.: US 2003/0096473 A1
(43) Pub. Date: May 22, 2003

(54) Method for making metal capacitors with low leakage currents for mixed-signal devices

(75) Inventors: Wong-Cheng Shih, Hsin-Chu (TW); Wenchi Ting, Hsin-Chu (TW); Tzyh-Cheang Lee, Hsin-Chu (TW); Chin-Hsien Lin, Hsin-Chu (TW); Shyh-Chyi Wong, Taichung (TW)

Correspondence Address: GEORGE O. SAILE & ASSOCIATES, 28 DAVIS AVENUE, POUGHKEEPSIE, NY, 12603, US

(73) Assignee: Taiwan Semiconductor Manufacturing Company

(21) Appl. No.: 09/992,458

(22) Filed: Nov. 16, 2001

(51) Int. Cl. H01L 21/8242

(52) U.S. Cl. 438/240

(57) ABSTRACT

A method for making metal-insulator-metal (MIM) capacitors having insulators with high-dielectric-constant and sandwiched between wide-band-gap insulators resulting in low leakage currents and high capacitance per unit area is achieved. The high-k layer increases the capacitance per unit area for next generation mixed-signal devices while the wide-band-gap insulators reduce leakage currents. In a second embodiment, a multilayer of different high-k materials is formed between the wide-band-gap insulators to substantially increase the capacitance per unit area. The layer materials and thicknesses are optimized to reduce the nonlinear capacitance dependence on voltage.

### BACKGROUND OF THE INVENTION

(1) Field of the Invention

The present invention relates to a method for making multilayer metal-insulator-metal capacitors for ultra-large-scale integration (ULSI), and more particularly relates to a method for making small metal capacitors with increased capacitance per unit area with lower leakage currents. This sandwiched capacitor uses a high-k dielectric film having a narrow band gap sandwiched between two insulating layers having a wide band gap. This structure allows one to reduce leakage currents while also allowing one to minimize the high-order coefficients for the capacitance-versus-voltage curve and to provide capacitors with are lower voltage-dependent.

(2) Description of the Prior Art

Capacitors on semiconductor chips are used for various integrated circuit applications. For example, these on-chip capacitors can be used as decoupling capacitors to provide improved voltage regulation and noise immunity for power distribution. These metal-insulator-metal (MIM) capacitors also have applications in analog/logic circuits (mixed-signal applications).

Typically these capacitors are integrated into the semiconductor circuit when the semiconductor devices are formed on the substrate. In early versions of MIM capacitors, the patterned conductively doped polysilicon layers were used to make the capacitor electrodes while forming the field effect transistors (FETs) and/or bipolar transistors. Alternatively, the capacitors can be fabricated using the multilevels of metal (e.g., metal silicide, Al/Cu, TiN etc.), which are also used to electrically interconnect (wire up) the individual semiconductor devices.

Generally the capacitors can be integrated into the circuit with few or with no additional process steps. When doped polysilicon layers are used for the capacitor electrodes, the voltage coefficient (delta C/delta V) of the capacitor can be high. That is because the capacitance C is also a function of the space charge layer in the semiconductor material, which is strongly voltage-dependent.

By far the best method of minimizing the voltage coefficient (delta C/delta V) is to replace the polysilicon with a high electrical conductivity material, such as metal, to form the capacitor having a constant spacing between the electrodes.

For very high-density circuits it is also desirable to increase capacitance while reducing the capacitor. This is achieved by replacing the thin dielectric layer having a low-dielectric-constant material, such as SiO₂, with a high-dielectric-constant material (high-k), such as Ta₂O₅, Si₃N₄, and the like. Unfortunately, these high-k dielectrics have a higher leakage current and lower breakdown voltages.

Several methods of making these high-k dielectric capacitors have been reported in the literature and filed as patents. Most of these patents improve the leakage current in the high-k dielectric by treating, such as by annealing in selected ambients, by plasma treatments, and by using electrically conducting barrier layers to prevent diffusion of O₂, H₂, carbon, and the like. For example, in U.S. Pat. No. 5,406,447 to Miyazaki, a metal barrier composed of TiN is used in contact with the dielectric film to prevent a spurious oxide film from growing and making the capacitors unreliable. In U.S. Pat. No. 6,207,488 B1 to twang et al., a high-k dielectric composed of Ta₂O₅ is treated by rapid thermal anneal (RTA) in nitrogen to improve the dielectric properties. In U.S. Pat. No. 6,201,276 B1 to Agarwal et al., a bottom electrode is formed from a conductor, such as TiN, Ta, W, Si, and the like, and a thin dielectric layer, such as silicon nitride, silicon oxide, tantalum oxide, is deposited directly on the bottom electrode. The top surface of the dielectric is then exposed to a reactive gas to form a passivation layer to prevent O₂, carbon (C), etc. from transporting between the dielectric layer and the top electrode. In U.S. Pat. No. 6,204,203 B1 to Narwankar et al., a polysilicon bottom electrode is formed and the surface is converted to a Si₃N₄. A high-k dielectric, such as Ta₂O₅, TiO₂, BST or PZT, is deposited, and an anneal is carried out to reduce carbon atoms at the bottom electrode-dielectric interface to reduce leakage currents. In U.S. Pat. No. 5,936,831 to Kola et al., the bottom electrode is made of chromium (Cr), a TaNₓ or Ta₂Si layer is deposited and is anodically oxidized to form a Ta₂O₅N_{y} from the TaNₓ, or TaSiₓO_{y} from the Ta₂Si. Then a counter electrode (top electrode) is formed from Cr. In U.S. Pat. No. 5,923,056 to Lee et al., a doped dielectric film formed from the Group III or Group VB elements, such as Ta₂O₅ and V₂O₅ (see periodic table), is doped during deposition with elements from the Group IV elements (Zr, Si, Ti, and Hf) to reduce interface states and tunneling leakage currents, for example in FET gate oxides. In U.S. Pat. No. 6,207,489 B1 to Nam et al., the bottom electrode is formed and a pretreatment film, such as silicon oxide, silicon nitride is formed on the bottom electrode. A dielectric film is formed using a Ta precursor. The dielectric film is deposited at two different temperatures and the film is thermally treated in oxygen. And in U.S. Pat. No. 5,468,687 to Carl et al., an anneal in ozone-enhanced plasma is used to reduce the anneal temperature for Ta₂O₅ for low temperature (400° C.) processing while achieving comparable quality as conventional higher temperature processing.

There is still a need in the semiconductor industry to form metal capacitors having high-k dielectrics with high unit capacitance, reduced leakage current, increased breakdown voltages and reduced capacitor dependence on applied voltage.

### SUMMARY OF THE INVENTION

A principal object of the present invention is to provide a metal-insulator-metal capacitor comprised of a sandwiched layer of a wide-band-gap oxide, a high-k dielectric film, and a second wide-band-gap oxide, which provides high capacitance per unit area, and low leakage currents between capacitor electrodes.

A second object of this invention is to provide this improved capacitor by sandwiching a high-k dielectric between two wide-band-gap oxide layers. The wide-band-gap oxide layers are in direct contact with the metal bottom and top electrodes to minimize thermionic emission and thereby reduce leakage current.

A third object of this invention is to vary the thicknesses of the wide-band-gap oxide layers and the high-k dielectric film to lower the capacitance second-order dependence on voltage (reduced coefficient).

A fourth object of this invention, by a second embodiment, is to form a high-k dielectric multilayer film to control the MIM capacitance and to lower the capacitance second-order dependence on voltage (reduced coefficient).

In accordance with the objects of the present invention, a method is described for making metal-insulator-metal (MIM) capacitors on a substrate having devices. By a first embodiment a first conducting electrode, such as TiN, is formed on the substrate. A wide-band-gap insulating layer, such as SiO₂ or Al₂O₃, is deposited directly on the first conducting electrode. Next a high-dielectric-constant film (high-k material such as Ta₂O₅) is deposited, and a second wide-band-gap insulating layer is deposited. The capacitor is then completed by forming a second conducting electrode directly on the second wide-band-gap insulating layer. The wide-band-gap insulators reduce the leakage current while the high-k dielectric film increases the capacitance per unit area. The linear dependence of the capacitance-versus-voltage curve can be improved by varying the thicknesses of the individual layers in the sandwiched layer and in combination with the treatment of the dielectric films and the interfaces between the dielectric films and the electrodes.

In a second embodiment of this invention, the high-dielectric-constant film is formed from a series of high-dielectric materials, such as Ta₂O₅, Si₃N₄, TiO₂, ZrO₂, HfO₂ between the two wide-band-gap insulating layers. By forming a multilayer dielectric film one can engineer the desired capacitance per unit area and the capacitance dependence on voltage (linearity).

### BRIEF DESCRIPTION OF THE DRAWINGS

The objects and other advantages of this invention are best understood with reference to the preferred embodiments when read in conjunction with the following drawings.

FIGS. 1 through 4 show schematic cross-sectional views for the sequence of process steps for forming the metal-insulator-metal (MIM) capacitors having high capacitance per unit area and low leakage current by the method of a first embodiment

FIG. 5 shows a schematic cross-sectional view of a MIM capacitor and in which, by a second embodiment, a multilayer of high-k materials replaces the single high-dielectric insulating film of the first embodiment.

### DESCRIPTION OF THE PREFERRED EMBODIMENTS

The present invention relates to a method for making metal-insulator-metal (MIM) capacitors on a partially completed substrate having devices. Typically the substrate is a semiconductor material, such as a doped single-crystal silicon, gallium arsenide, or the like. After forming semiconductor devices such as FETs, bipolar transistors, and the like in and on the substrate, the devices are insulated, and the MIM capacitors are formed having electrical connections to the devices.

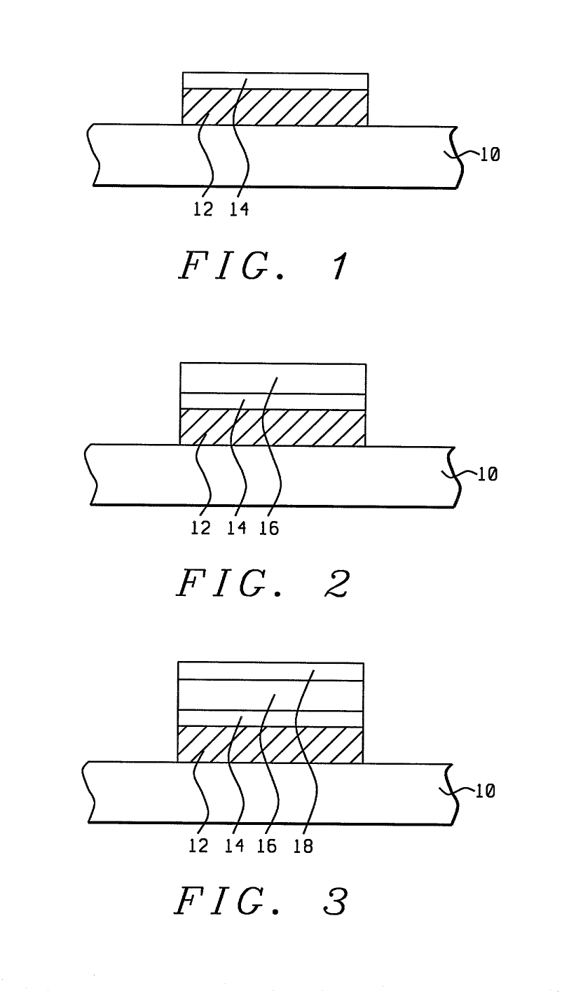

Referring first to FIG. 1, a schematic cross-sectional view is shown of a portion of a semiconductor substrate 10 having devices (not shown). By a first embodiment of this invention, the method for making the MIM capacitors begins by depositing a first conducting layer. The first conducting layer is then patterned to form the capacitor bottom electrodes 12. The first conducting layer is preferably titanium nitride (TiN), deposited, for example, by physical vapor deposition such as by sputtering from a Ti target in a reactant gas such as nitrogen. The first conducting layer is deposited to a preferred thickness of between about 200 and 1000 Angstroms. The first conducting layer is patterned using reactive ion etching (RIE) to form the first conducting electrodes 12.

Still referring to FIG. 1, a first wide-band-gap insulating layer 14, such as SiO₂ or Al₂O₃, is deposited directly on the bottom electrodes 12. SiO₂ insulating layer 14 can be deposited, for example, by chemical-vapor deposition (CVD) using a reactant gas such as tetraethosiloxane (TEOS). The SiO₂ layer 14 can be deposited to a preferred thickness of between about 10 and 50 Angstroms. Alternatively, insulating layer 14 can be Al₂O₃, deposited, for example, by CVD or atomic layer CVD (ALCVD) techniques to a preferred thickness of between about 10 and 50 Angstroms.

Referring to FIG. 2, a high-dielectric-constant film 16 is formed over insulating layer 14. Layer 16 can be composed of a high-k material, such as Ta₂O₅, Si₃N₄, TiO₂, ZrO₂, or HfO₂. For example, the Ta₂O₅ can be deposited by CVD or by ALCVD. The Si₃N₄ can be deposited by CVD. The TiO₂ can be deposited by CVD. The HfO₂ and the ZrO₂ can be deposited by physical vapor deposition, for example by using physical sputtering techniques. To improve the quality of this high-dielectric film, the film is treated in a gas such as O₂, N₂, N₂O, NH₃, and using a thermal treatment, such as rapid thermal anneal or in an oxidation furnace and/or plasma treatment, in order to purify and oxidize the film 16. For example, the rapid thermal anneal can be carried out at a preferred temperature of between about 300 and 700° C. for between about 1 and 260 seconds. This above treatment is used to purify the film 16 by reducing the C, H, and Cl in the film and further oxidizes the film to reduce leakage current. Concurrently during the same treatment, the film 16 can be crystallized for some materials to improve the dielectric constant and thereby provide improved capacitance. The high-k dielectric film 16 is formed to a preferred thickness of between about 50 and 800 Angstroms.

Referring to FIG. 3, a second wide-band-gap insulating layer 18 is deposited on the high-k layer 16. The second wide-band-gap insulating layer 18 is also composed of Si0₂ or Al₂O₃, and is deposited directly on the high-k layer 16, and immediately before depositing the conducting layer for the top electrodes. The SiO₂ second wide-band-gap insulating layer 18 is deposited, for example, by CVD using a reactant gas such as TEOS. The SiO₂ layer 18 has a preferred thickness of between about 10 and 50 Angstroms. Alternatively, second insulating layer 18 can be Al₂O₃, deposited, for example, by CVD to a preferred thickness of between about 10 and 50 Angstroms.

Referring to FIG. 4, the MIM capacitor is then completed by depositing a second electrically conducting layer directly on the second wide-band-gap insulating layer 18. The second conducting layer is preferably TiN, deposited, for example, by PVD or by ALCVD. The TiN is deposited to a preferred thickness of between about 200 and 1000 Angstroms. The second conducting layer is patterned to form the capacitor top electrodes 20 on the second wide-band-gap insulating layer 18. The second conducting layer is patterned using reactive ion etching (RIE).

The wide-band-gap insulators, layers 14 and 18, in direct contact with the bottom electrodes 12 and top electrodes 20, respectively, reduce the thermionic emission thereby reducing leakage current, while the high-k dielectric film 16 is used to increase the capacitance per unit area. This allows the MIM capacitor to be scaled down in area for the 0.13-micrometer generation mixed-signal devices.

The capacitance-versus-voltage curve for the capacitor is

C/C₀=a₁V+a₂V²+. . .

where C/C₀ is the ratio of the change of capacitance to capacitance, and a₁ and a₂ are the coefficients for the linear term and the quadratic term, respectively. The higher-order terms are not shown in the above equation.

One objective of the invention is to use the different film properties (wide-band gap and high-k) to minimize the coefficients a₂ and a₁ to achieve low capacitance dependence on voltage. For example, it is desirable to provide an a₂ of less than 50 parts per million (ppm)/voltage squared. The non-linear dependence of the capacitance-versus-voltage curve can be improved by varying the thicknesses of the individual layers in the sandwiched layer, and by treatment of the dielectric layers and the interfaces between the electrodes and the dielectric layers.

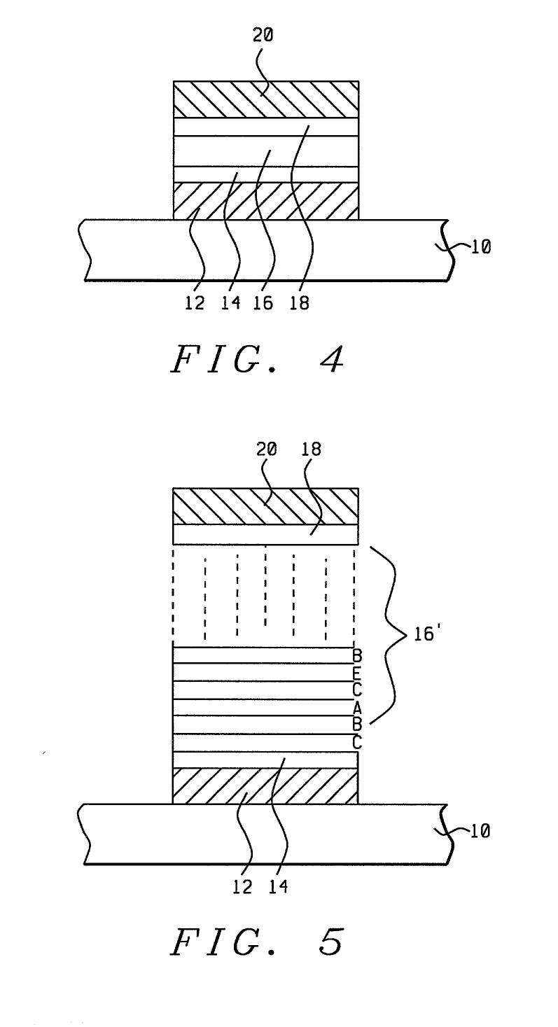

Referring to FIG. 5, a second embodiment of this invention is now described. The second embodiment is similar to the first embodiment in which a wide-band-gap layer 14 is formed directly on the bottom electrode 12, and a wide-band-gap layer 18 is in direct contact with the bottom surface of the top electrode 20 to reduce leakage currents. In the second embodiment a high-dielectric multilayer 16′ composed of several different high-k materials replaces the single high-k layer 16 of the first embodiment. The multilayer 16′ can be composed of a series of layers 16A through 16E of varying high-dielectric materials, and can be deposited in any order or sequence, as depicted in FIG. 5, to achieve the desired properties for mixed-signal devices. For example, layers 16A through 16E can be the high-k materials, such as Ta₂O₅, Si₃N₄, TiO₂, ZrO₂, HfO₂. By forming a multilayer dielectric film 16′ one can further control the value of the high-k capacitors while reducing the nonlinear dependence of the capacitance on applied voltage.

While the invention has been particularly shown and described with reference to the preferred embodiments thereof, it will be understood by those skilled in the art that various changes in form and details may be made without departing from the spirit and scope of the invention.

What is claimed is:

1. A method for making a metal-insulator-metal capacitor on a substrate comprising the steps of:
forming bottom electrodes from a first conducting layer on said substrate;
depositing a first wide-band-gap insulating layer on said bottom electrodes;
depositing a high-k dielectric film over said wide-band-gap insulating layer;
depositing a second wide-band-gap insulating layer over said high-k dielectric film;
forming top electrodes from a second conducting layer on said second wide-band-gap insulating layer.

2. The method of claim 1, wherein said bottom electrodes and said top electrodes are formed from a material selected from the group that includes titanium nitride, tantalum nitride, tungsten nitride, ruthenium, iridium, iridium oxide, and platinum, and is deposited to a thickness of between about 200 and 1000 Angstroms.

3. The method of claim 1, wherein said first and said second wide-band-gap insulating layers are materials selected from the group that includes silicon dioxide and aluminum oxide.

4. The method of claim 1, wherein said high-k dielectric film is a material selected from the group that includes tantalum pentoxide, silicon nitride, titanium oxide, zirconium oxide, and hafnium oxide.

5. The method of claim 4, wherein said high-k dielectric film is deposited by physical vapor deposition.

6. The method of claim 4, wherein said high-k dielectric film is deposited by chemical vapor deposition.

7. The method of claim 4, wherein said high-k dielectric film is deposited by atomic layer chemical vapor deposition.

8. The method of claim 4, wherein said high-k dielectric film is deposited to a thickness of between about 50 and 800 Angstroms.

9. The method of claim 4, wherein said high-k dielectric film is treated in a gas selected from the group that includes oxygen, nitrogen, nitrous oxide, and ammonia, and rapid thermally annealed at a temperature of between about 300 and 700° C. for a time of between about 1 and 260 seconds.

10. A method for making a metal-insulator-metal capacitor on a substrate comprising the steps of:
forming bottom electrodes composed of titanium nitride on said substrate;
depositing a first wide-band-gap insulating layer composed of aluminum oxide over said bottom electrodes;
depositing a high-k dielectric film composed of tantalum pentoxide over said wide-band-gap insulating layer;
depositing a second wide-band-gap insulating layer composed of aluminum oxide over said high-k dielectric film;
forming top electrodes composed of titanium nitride over said second wide-band-gap insulating layer.

11. The method of claim 10, wherein said bottom electrodes and said top electrodes composed of titanium nitride have a thickness of between about 200 and 1000 Angstroms.

12. The method of claim 10, wherein said first and said second wide-band-gap insulating layers composed of aluminum oxide have a thickness of between about 10 and 50 Angstroms.

13. The method of claim 10, wherein said high-k dielectric film composed of tantalum pentoxide has a thickness of between about 50 and 800 Angstroms.

14. The method of claim 10, wherein said tantalum pentoxide is deposited by chemical vapor deposition.

15. The method of claim 10, wherein said tantalum pentoxide is treated in a gas selected from the group that includes oxygen, nitrogen, nitrous oxide, and ammonia, and is rapid thermally annealed at a temperature of between about 300 and 700° C. for a time of between 1 and 260 seconds.

16. A method for making a metal-insulator-metal capacitor on a substrate comprising the steps of:
forming bottom electrodes on said substrate;
depositing a first wide-band-gap insulating layer over said bottom electrodes;
depositing a multilayer of high-k dielectric films over said wide-band-gap insulating layer;
depositing a second wide-band-gap insulating layer over said multilayer;
forming top electrodes over said second wide-band-gap insulating layer.

17. The method of claim 16, wherein said bottom electrodes and said top electrodes are formed from a material selected from the group that includes titanium nitride, tantalum nitride, tungsten nitride, ruthenium, iridium, iridium oxide, and platinum.

18. The method of claim 17, wherein said material is deposited to a thickness of between about 200 and 1000 Angstroms.

19. The method of claim 17, wherein said multilayer of high-k dielectric films is composed of materials selected from the group that includes tantalum pentoxide, silicon nitride, titanium oxide, zirconium oxide and hafnium oxide.

20. The method of claim 17, wherein each layer of said multilayer of high-k dielectric films is treated in a gas selected from the group that includes oxygen, nitrogen, nitrous oxide, and ammonia, and rapid thermally annealed at a temperature of between about 300 and 700° C. for a time of between about 1 and 260 seconds.
